(19) United States
(12) Patent Application Publication
(10) Pub. No.: US 2022/0248530 A1
(43) Pub. Date: Aug. 4, 2022

(54) WIRING SUBSTRATE

(71) Applicant: IBIDEN CO., LTD., Ogaki (JP)

(72) Inventors: Yoji MORI, Ogaki (JP); Mamoru FUKUNAGA, Ogaki (JP); Shota TACHIBANA, Ogaki (JP)

(73) Assignee: IBIDEN CO., LTD., Ogaki (JP)

(21) Appl. No.: 17/580,141

(22) Filed: Jan. 20, 2022

(30) Foreign Application Priority Data
Feb. 4, 2021 (JP) 2021-016927

(51) Int. Cl. H05K 1/03; H05K 1/11

(52) U.S. Cl. CPC H05K 1/0306; H05K 1/111; H05K 2201/09509; H05K 2201/0275; H05K 1/115

(57) ABSTRACT

A wiring substrate having no core substrate includes a build-up layer including insulating layers and conductor layers such that the insulating layers include first, second, third and fourth insulating layers and that the conductor layers include a first conductor layer formed on the first insulating layer and a second conductor layer formed on the second insulating layer. The build-up layer has a first surface having the first insulating and first conductor layers, a second surface having the second insulating and second conductor layers, the third insulating layer formed on the first insulating layer on the opposite side of the first conductor layer, and the fourth insulating layer formed on the second insulating layer on the opposite side of the second conductor layer, and the build-up layer is formed such that the first and second insulating layers contain no core material and the third and fourth insulating layer include core material.

### CROSS-REFERENCE TO RELATED APPLICATIONS

The present application is based upon and claims the benefit of priority to Japanese Patent Application No. 2021-016927, filed Feb. 4, 2021, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2004-186265 describes a method for manufacturing a multilayer wiring substrate in which a plate-shaped base material for reinforcing strength of build-up layers that each include insulating layers and wiring layers is prepared and the build-up layers are respectively formed front and back sides of the plate-shaped base material. After the formation of the build-up layers, the build-up layers on the front and back sides of the plate-shaped base material are separated from the plate-shaped base material. The entire contents of this publication are incorporated herein by reference.

### SUMMARY OF THE INVENTION

According to one aspect of the present invention, a wiring substrate having no core substrate includes a build-up layer including insulating layers and conductor layers such that the insulating layers include a first insulating layer, a second insulating layer, a third insulation layer and a fourth insulating layer and that the conductor layers include a first conductor layer formed on the first insulating layer and a second conductor layer formed on the second insulating layer. The build-up layer has a first surface having the first insulating layer and the first conductor layer, a second surface having the second insulating layer and the second conductor layer on the opposite side with respect to the first surface of the build-up layer, the third insulating layer formed on the first insulating layer on the opposite side with respect to the first conductor layer, and the fourth insulating layer formed on the second insulating layer on the opposite side with respect to the second conductor layer, and the build-up layer is formed such that the first insulating layer and the second insulating layer contain no core material and that each of the third insulating layer and the fourth insulating layer includes a core material.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2A illustrates an example of a method for manufacturing a wiring substrate according to an embodiment of the present invention;

FIG. 2B illustrates an example of the method for manufacturing a wiring substrate according to the embodiment of the present invention;

FIG. 2C illustrates an example of the method for manufacturing a wiring substrate according to the embodiment of the present invention;

FIG. 2D illustrates an example of the method for manufacturing a wiring substrate according to the embodiment of the present invention; and

FIG. 2E illustrates an example of the method for manufacturing a wiring substrate according to the embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

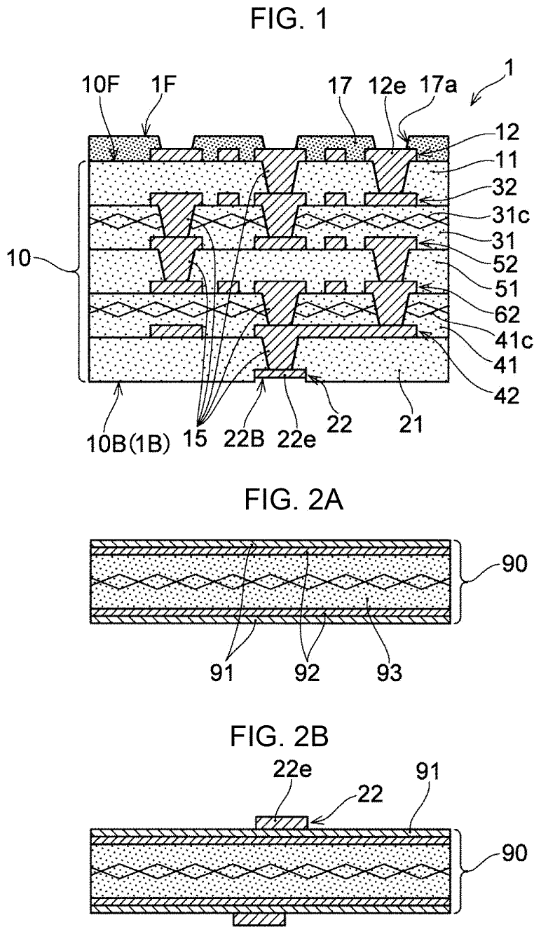

A wiring substrate of an embodiment of the present invention is described with reference to the drawings. FIG. 1 is a cross-sectional view illustrating a wiring substrate 1, which is an example of the wiring substrate of the embodiment.

As illustrated in FIG. 1, the wiring substrate 1 includes a build-up layer 10 having two main surfaces (a first surface (10F) and a second surface (10B) on the opposite side with respect to the first surface (10F)) opposing each other in a thickness direction thereof in which multiple insulating layers (11, 21, 31, 41, 51) and multiple conductor layers (12, 22, 32, 42, 52, 62) are alternately laminated. The first surface (10F) of the build-up layer 10 is formed of surfaces of the first insulating layer 11 and the first conductor layer 12 that are exposed on one side in a lamination direction of the build-up layer 10. Further, the second surface (10B) of the build-up layer 10 is formed of surfaces of the second insulating layer 21 and the second conductor layer 22 that are exposed on the other side in the stacking direction of the build-up layer 10. A solder resist layer 17 is formed on the first insulating layer 11 and the first conductor layer 12. The wiring substrate 1 does not have a core substrate.

In the example of FIG. 1, from the second surface (10B) side to the first surface (10F) side of the build-up layer 10, the second conductor layer 22, the second insulating layer 21, the fourth conductor layer 42, the fourth insulating layer 41, the sixth conductor layer 62, the fifth insulating layer 51, the fifth conductor layer 52, the third insulating layer 31, the third conductor layer 32, the first insulating layer 11, and the first conductor layer 12 are laminated in this order.

The second conductor layer 22 is embedded in the second insulating layer 21 and a surface thereof is exposed on the second surface (10B) of the build-up layer 10. In this way, embedding the second conductor layer 22 in the second insulating layer 21 contributes to reduction in thickness of the wiring substrate 1. The second conductor layer 22 includes one or more conductor pads (22e). Surfaces (22B) of the conductor pads (22e) are recessed relative to the second surface (10B) of the build-up layer 10. Side surfaces of the conductor pads (22e) are covered by the second insulating layer 21. Therefore, it is considered that contact between bonding members such as solders of adjacent conductor pads is unlikely to occur. It is considered that a short circuit failure is unlikely to occur.

In the wiring substrate 1 of the embodiment, the first insulating layer 11, the first conductor layer 12, and the solder resist layer 17 form a surface layer part on a first surface (1F) side of the wiring substrate 1. The first surface (1F) is formed of exposed surfaces of the first insulating layer 11, the first conductor layer 12, and the solder resist layer 17. Further, the second insulating layer 21 and the second conductor layer 22 form a surface layer part on a second surface (1B) side of the wiring substrate 1. The second surface (1B) is formed of exposed surfaces of the second insulating layer 21 and the second conductor layer 22.

In the wiring substrate 1 of FIG. 1, the build-up layer 10 is formed of five insulating layers (11, 21, 31, 41, 51) and six conductor layers (12, 22, 32, 42, 52, 62), which are alternately laminated. That is, FIG. 1 illustrates an example of the build-up wiring layer 10 having a so-called six-layer structure. However, the number of the insulating layers and the number of the conductor layers are not limited to this example, and is appropriately selected according to a desired circuit structure. The build-up layer 10 may include any number of, for example, 6 or more insulating layers and 7 or more conductor layers.

The conductor layers (12, 22, 32, 42, 52, 62) are formed using any metal. For example, each of the conductor layers (12, 22, 32, 42, 52, 62) may be formed of a metal foil such as copper foil or a metal film formed by plating or sputtering or the like. In the example illustrated in FIG. 1, the conductor layers (12, 32, 42, 52, 62) are each illustrated as a single layer. However, each of the conductor layers (12, 32, 42, 52, 62) may be formed to have a multilayer structure. For example, each of the conductor layers (12, 32, 42, 52, 62) may be formed to have a three-layer structure including a metal foil layer, an electroless plating film layer, and an electrolytic plating film layer. Further, the conductor layers (12, 22, 32, 42, 52, 62) may each be formed to have a two-layer structure including an electroless plating film layer and an electrolytic plating film layer. Each of the conductor layers (12, 22, 32, 42, 52, 62) can be formed, for example, using any metal such as copper or nickel alone or using two or more of these metals in combination. For example, the conductor layers (12, 22, 32, 42, 52, 62) can be formed of copper, which allows easy formation by electrolytic plating and has excellent conductivity.

In each of the conductor layers (12, 22, 32, 42, 52, 62), desired conductor patterns including wiring patterns and/or conductor pads are formed. In the wiring substrate 1 of the example illustrated in FIG. 1, the first conductor layer 12 includes component mounting pads (12e). That is, the wiring substrate 1 includes the component mounting pads (12e) on the first surface (1F). As illustrated in FIG. 1, the component mounting pads (12e) are formed on the first insulating layer 11.

In the example of FIG. 1, the wiring substrate 1 includes the solder resist layer 17 formed on the surfaces of the first insulating layer 11 and the first conductor layer 12. The solder resist layer 17 is formed using, for example, a photosensitive polyimide resin or epoxy resin. The solder resist layer 17 has openings (17a) that define the component mounting pads (12e). The component mounting pads (12e) are exposed in the openings (17a) of the solder resist layer 17. Each of the component mounting pads (12e) may have any shape, and, for example, can be defined by the openings (17a) of the solder resist layer 17.

The component mounting pads (12e) are conductor pads that can be connected to an electronic component (not illustrated in the drawings) mounted on the wiring substrate 1 when the wiring substrate 1 is used. The component mounting pads (12e) may be electrically and mechanically connected to electrodes of an electronic component mounted on the first surface (1F) of the wiring substrate 1, for example, via bonding members (not illustrated in the drawings) such as solders. The component mounting pads (12e) may be formed at any positions and in any number according to wiring patterns of an electronic component mounted on the wiring substrate 1.

Examples of the electronic component include active components such as semiconductor devices and passive components such as resistors. The electronic component may be a wiring material including fine wirings formed on a semiconductor substrate. However, the electronic component is not limited to these.

The second surface (1B) of wiring substrate 1 of the embodiment can be connected to an external wiring substrate, for example, a motherboard or the like of any electrical device (not illustrated in the drawings). The conductor pads (22e) are connection pads to be connected to connection pads or the like on a motherboard. An electronic component (not illustrated in the drawings) such as a semiconductor element may be mounted on the second surface (1B) of the wiring substrate 1 of the embodiment. In that case, the conductor pads (22e) may be connected to electrodes of the electronic component mounted on the second surface (1B). The conductor pads (22e) may be formed at any positions and in any number according to wiring patterns of a motherboard connected to the second surface (1B) of the wiring substrate 1 or an electronic component mounted on the second surface (1B) of the wiring substrate 1.

In each of the insulating layers (11, 21, 31, 41, 51), via conductors 15 that penetrate the each of the insulating layers (11, 21, 31, 41, 51) and connect the conductor layers sandwiching the each of the insulating layers (11, 21, 31, 41, 51) are formed. The via conductors 15 are so-called filled vias formed by filling through holes penetrating the interlayer insulating layers (11, 21, 31, 41, 51) with conductors. Each of the via conductors 15 is integrally formed with a conductor layer on an upper side thereof. Therefore, for example, the via conductors 15 and the conductor layers (12, 32, 42, 52, 62) are formed by the same plating films (an electroless plating film and an electrolytic plating film) of, for example, copper or nickel. The through holes for forming the via conductors 15 can be formed, for example, by irradiating laser to a surface on one side of each insulating layer. A diameter of each of the through holes is larger on a laser irradiation side and becomes smaller on the opposite side (deep side) with respect to the laser irradiation side. In the example illustrated in FIG. 1, since laser is irradiated from the upper side of FIG. 1, an upper diameter (width) of each of the through holes is larger and a lower diameter (width) of each of the through holes is smaller. Therefore, the via conductors that are respectively formed in the through holes also each have a larger upper width (diameter) and a smaller lower width (diameter). In the example illustrated in FIG. 1, the via conductors are each formed in a tapered shape that is reduced in diameter from the first surface (10F) toward the second surface (10B) of the build-up layer 10. For convenience, the term “reduced in diameter” is used. However, a shape of each of the via conductors 15 is not necessarily limited to a circular shape. The term “reduced in diameter” means that a longest distance between two points on an outer circumference of a horizontal cross section of each of the via conductors 15 is reduced.

The insulating layers (11, 21, 31, 41, 51) are formed of any insulating resin. Examples of the insulating resin include an epoxy resin, a bismaleimide triazine resin (BT resin), a phenol resin, and the like. The insulating layers (11, 21, 31, 41, 51) may each contain an inorganic filler. Examples of the inorganic filler contained in each of the insulating layers include fine particles formed of silica (SiO₂), alumina, or mullite.

As illustrated in FIG. 1, in the wiring substrate 1 of the embodiment, the outermost insulating layer on the first surface (1F) side of the wiring substrate 1 (that is, the outermost insulating layer, which is the first insulating layer 11, that forms the first surface (10F) of the build-up layer 10) contains no core material (reinforcing material). The outermost insulating layer on the second surface (1B) side (that is, the outermost insulating layer, which is the second insulating layer 21, that forms the second surface (10B) of the build-up layer 10) also contains no core material. In contrast, the two insulating layers, that is, the third insulating layer 31 and the fourth insulating layer 41, each contain a core material impregnated with an insulating resin (in the example of FIG. 1, the core materials are respectively a core material (31c) and a core material (41c)). The third insulating layer 31 is formed on the first insulating layer 11 on the opposite side with respect to the first conductor layer 12 and is at least partially in contact with the first insulating layer 11. The fourth insulating layer 41 is formed on the second insulating layer 21 on the opposite side with respect to the second conductor layer 22 and is at least partially in contact with the second insulating layer 21.

Examples of the core materials include, but are not limited to, a glass fiber, an aramid fiber, and the like. Each of the third insulating layer 31 and the fourth insulating layer 41 can be formed of, for example, a cured product of a prepreg obtained by impregnating a core material such as glass fiber with a resin material such as an epoxy resin. However, the material of the third insulating layer 31 and the fourth insulating layer 41 is not limited to this, and may be, for example, a build-up resin film containing a glass fiber.

The insulating layers that respectively form the outermost layers exposed on the surfaces of the build-up layer 10 on both the first surface (1F) side and the second surface (1B) side of the wiring substrate 1 contain no core material, and thereby, high density wirings can be formed. On the other hand, the two insulating layers (the third insulating layer 31 and the fourth insulating layer 41 in the example of FIG. 1) that are insulating layers in the build-up layer 10 and are respectively formed on inner sides of and in contact with the outermost insulating layers on both the first surface (10F) side and the second surface (10B) side each contain a core material (the core material (31c) and the core material (41c) in FIG. 1). In this way, by including the insulating layers that are respectively adjacent to the outermost insulating layers and each contain a core material in the build-up layer 10, even when the outermost insulating layers contain no core material, rigidity of the wiring substrate 1 is maintained, and mechanical strength of the wiring substrate 1 is maintained or improved. In the present embodiment, on both the first surface (1F) side and the second surface (1B) side of the wiring substrate 1, an outermost insulating layer that contains no core material is formed on an insulating layer that contains a core material. By having such a structure, while achieving a high density and a fine pitch in the wiring substrate 1, occurrence of warpage in the wiring substrate 1 is suppressed.

In the example illustrated in FIG. 1, further, in the build-up layer 10, an insulating layer (the fifth insulating layer 51) that is laminated and sandwiched between the third insulating layer 31 containing the core material (31c) and the fourth insulating layer 41 containing the core material (41c) is formed of an insulating resin containing no core material. FIG. 1 illustrates an example in which one insulating layer is formed and sandwiched between the third insulating layer 31 and the fourth insulating layer 41. However, not only one insulating layer but also multiple insulating layers may be formed and sandwiched between the third insulating layer 31 and the fourth insulating layer 41. The number of the insulating layers formed between the third insulating layer 31 and the fourth insulating layer 41 is appropriately selected according to a desired circuit structure. Preferably, at least one insulating layer is formed between the third insulating layer 31 and the fourth insulating layer 41. More preferably, at least one insulating layer containing no core material is formed between the third insulating layer 31 and the fourth insulating layer 41. That is, when multiple insulating layers are formed between the third insulating layer 31 and the fourth insulating layer 41, preferably, among the multiple insulating layers, at least one insulating layer contains no core material. When the build-up layer 10 has such a structure of insulating layers, it may be possible to further satisfactorily suppress occurrence of warpage in the wiring substrate 1.

Although not illustrated in the drawings, a protective film may be formed on the exposed surfaces of the component mounting pads (12e), which are defined by the openings (17a) of the solder resist layer 17, and the conductor pads (22e). Such a protective film may be a metal film or an organic film. For example, the protective film may include multiple metal plating films or a single metal plating film such as Ni/Au, Ni/Pd/Au, or Sn, or may be an imidazole-based OSP (Organic Solderability Preservative) film.

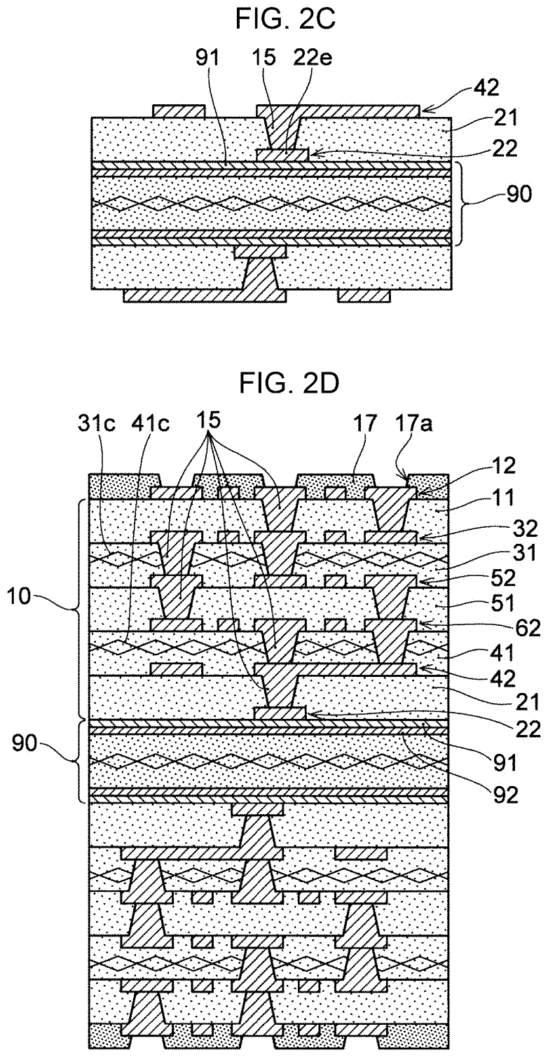

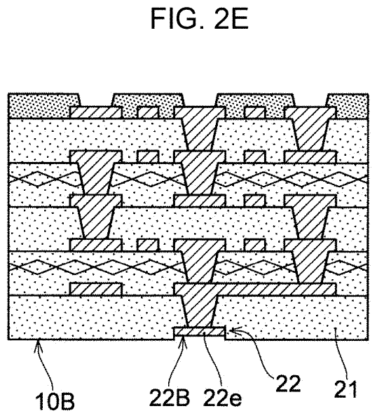

Next, an embodiment of a method for manufacturing the wiring substrate 1 illustrated in FIG. 1 is described with reference to FIGS. 2A-2E.

First, as illustrated in FIGS. 2A and 2B, the second conductor layer 22 including the conductor pads (22e) is formed on a base plate 90. As illustrated in FIG. 2A, the base plate 90 having a core material 93 and a metal foil 91 on a surface of the core material 93 is prepared. The metal foil 91 has a carrier metal foil 92 adhered to a surface of the metal foil 91, and the carrier metal foil 92 and the core material 93 are bonded to each other by thermocompression bonding or the like. The metal foil 91 and the carrier metal foil 92 are adhered to each other by, for example, a separable adhesive such as a thermoplastic adhesive, or are fixed to each other only at edges thereof. For the core material 93, for example, a glass epoxy substrate is used. It is also possible that a double-sided copper-clad laminated plate is used as the core material 90 having the carrier metal foil 92. The metal foil 91 and the carrier metal foil 92 are preferably copper foils.

FIGS. 2A-2D illustrate an example of a manufacturing method of the embodiment in which the second conductor layer 22 and the like are formed on both sides of the base plate 90. In such an example of the manufacturing method, two sets of the second conductor layer 22 and the like are simultaneously formed. However, it is also possible that the second conductor layer 22 and the like are formed on only one side of the base plate 90. In the following description, the manufacturing method of the embodiment is described with respect to one side of the base plate 90, and illustration and description of reference numeral symbols in the drawings with respect to the other side are omitted as appropriate. Further, in FIGS. 2A-2E, it is not intended to illustrate exact ratios of thicknesses of the structural elements.

As illustrated in FIG. 2B, the second conductor layer 22 is formed on the base plate 90. For example, a plating resist (not illustrated in the drawings) is formed on the metal foil 91. Openings corresponding to conductor patterns such as the conductor pads (22e) to be formed in the second conductor layer 22 are formed in the plating resist. Then, an electrolytic copper plating film is formed in the openings of the plating resist by electrolytic plating using the metal foil 91 as a seed layer, and after that, the plating resist is removed. As a result, the second conductor layer 22 including the desired conductor patterns such as the conductor pads (22e) is formed. Since etching is not used, the conductor patterns such as the conductor pads (22e) can be formed at a fine pitch. It is also possible that the second conductor layer 22 and the like are formed using other methods such as electroless plating.

As illustrated in FIGS. 2C and 2D, the insulating layers and the conductor layers are laminated on the base plate 90 and on the second conductor layer 22, and as a result, the build-up layer 10 (see FIG. 1) including the insulating layer (the second insulating layer 21) covering the second conductor layer 22 is formed. After that, the base plate 90 is removed. A common method for manufacturing a build-up wiring board may be used.

For example, a film-like insulating material mainly formed of an insulating resin is laminated on exposed portions of the second conductor layer 22 and the metal foil 91 and is pressed and heated. As the cured product, as illustrated in FIG. 2C, the second insulating layer 21 is formed. An example of the material of the second insulating layer 21 is an epoxy resin that contains no core material.

The second insulating layer 21 is formed so as to cover the second conductor layer 22 including the conductor pads (22e) except for a surface thereof on the metal foil 91 side. After that, the through holes for forming the via conductors 15 are formed in the second insulating layer 21 at positions corresponding to formation positions of the via conductors 15, for example, by irradiation with CO2 laser. Then, a metal film is formed by electroless copper plating or the like inside the through holes for forming the via conductors 15 and on the surface of the second insulating layer 21. Further, using this metal film as a seed layer, an electrolytic plating film formed of copper or the like is formed using a pattern plating method. After that, a resist used for the pattern plating is removed, and the metal film exposed by the removal of the resist is removed. As a result, the fourth conductor layer 42 including desired conductor patterns and the via conductors 15 are formed.

As illustrated in FIG. 2D, using the same method as the formation method of the second insulating layer 21, the fourth conductor layer 42 and the via conductors 15, on the second insulating layer 21 and the fourth conductor layer 42, the fourth insulating layer 41, the sixth conductor layer 62, the fifth insulating layer 51, the fifth conductor layer 52, the third insulating layer 31, the third conductor layer 32, the first insulating layer 11, and the first conductor layer 12 are formed in this order, and the via conductors 15 penetrating the insulating layers are formed. The insulating materials, which are the materials of the fifth insulating layer 51 and the first insulating layer 11, contain no core material. The insulating materials, which are the materials of the fourth insulating layer 41 and the third insulating layer 31, respectively contain the core materials (41c, 31c). The build-up layer 10 is formed on the base plate 90.

Next, the solder resist layer 17 is formed by forming a photosensitive epoxy resin or polyimide resin layer on surfaces of the first insulating layer 11 and the first conductor layer 12. Then, using a photolithography technology, the openings (17a) that respectively define the component mounting pads (12e) are formed.

After that, the base plate 90 is removed. Specifically, the carrier metal foil 92 and the metal foil 91 are separated from each other, and the metal foil 91 exposed by the separation is removed, for example, by etching. The separation of the metal foil 91 and the carrier metal foil 92 can be performed, for example, by softening, by heating, the thermoplastic adhesive that adheres the two to each other, or by cutting off a joining portion where the two are fixed to each other at the edges thereof. By removing the base plate 90, the second conductor layer 22 and the second insulating layer 2 are exposed. The metal foil 91 is removed by etching. However, even after the metal foil 91 has disappeared, the etching is continued such that the individual conductor patterns in the second conductor layer 22 are reliably separated from each other.

As a result, as illustrated in FIG. 2E, the surface of the second conductor layer 22 exposed after the metal foil 91 disappears is recessed relative to the surface of the second insulating layer 21 by being etched. Therefore, the surfaces (22B) of the conductor pads (22e) included in the second conductor layer 22 are also recessed relative to surface of the second insulating layer 21 (that is, the second surface (10B) of the build-up layer 10). In this way, when the surfaces (22B) of the conductor pads (22e) are recessed relative to the surface of the second insulating layer 21 surrounding the conductor pads (22e), wet spreading of bonding members such as solders that are respectively provided on the conductor pads (22e) is suppressed. For example, the surfaces (22B) of the conductor pads (22e) are recessed from the surface of the second insulating layer 21 at a depth of 1 μm or more and 6 μm or less. When the surfaces (22B) are recessed at such a depth, even when the conductor pads (22e) are formed at a fine pitch, it is considered that an effective effect of suppressing a short-circuit defect between adjacent conductor pads (22e) is obtained. The wiring substrate 1 illustrated in FIG. 1 is completed.

The wiring substrate of the embodiment is not limited to those having the structures illustrated in the drawings and those having the structures, shapes, and materials exemplified in the present specification. As described above, the wiring substrate of the embodiment may include, for example, a build-up layer 10 having a layer structure of 7 or more layers. Further, the method for manufacturing the wiring board of the embodiment is not limited to the method described with reference to FIGS. 2A-2E. The conditions, processing order and the like of the method may be arbitrarily modified. Further, it is also possible that a specific process is omitted or another process is added. For example, a protective film may be formed on each of the component mounting pads (12e) and the conductor pads (22e). For example, the protective film formed of Ni/Au, Ni/Pd/Au, Sn or the like can be formed by plating. An OSP may be formed by immersion in a liquid organic material or by spraying an organic material.

In the method for manufacturing the multilayer wiring substrate of Japanese Patent Application Laid-Open Publication No. 2004-186265, the strength of the build-up layers during formation is maintained by the plate-shaped base material. It is thought that the strength of the build-up layers after being separated from the plate-shaped base material is not sufficient, and there is a risk that a defect may occur during component mounting.

A wiring substrate according to an embodiment of the present invention has no core substrate and includes a build-up layer in which insulating layers and conductor layers are alternately laminated. The build-up layer has a first surface that is formed of a first insulating layer and a first conductor layer, and a second surface that is formed of a second insulating layer and a second conductor layer and is on the opposite side with respect to the first surface. The build-up layer further includes a third insulating layer that is formed on the first insulating layer on the opposite side with respect to the first conductor layer and is at least partially in contact with the first insulating layer; and a fourth insulating layer that is formed on the second insulating layer on the opposite side with respect to the second conductor layer and at least partially in contact with the second insulating layer. The first insulating layer and the second insulating layer contain no core material. The third insulating layer and the fourth insulating layer each contain a core material.

In a wiring substrate according to an embodiment of the present invention, it is thought that rigidity of the wiring substrate is improved and occurrence of a defect such as warpage is unlikely to occur. A wiring substrate having a high mounting reliability is provided.

Obviously, numerous modifications and variations of the present invention are possible in light of the above teachings. It is therefore to be understood that within the scope of the appended claims, the invention may be practiced otherwise than as specifically described herein.

What is claimed is:

1. A wiring substrate having no core substrate, comprising:
a build-up layer comprising a plurality of insulating layers and a plurality of conductor layers such that the plurality of insulating layers includes a first insulating layer, a second insulating layer, a third insulation layer and a fourth insulating layer and that the plurality of conductor layers includes a first conductor layer formed on the first insulating layer and a second conductor layer formed on the second insulating layer,
wherein the build-up layer has a first surface having the first insulating layer and the first conductor layer, a second surface having the second insulating layer and the second conductor layer on an opposite side with respect to the first surface of the build-up layer, the third insulating layer formed on the first insulating layer on an opposite side with respect to the first conductor layer, and the fourth insulating layer formed on the second insulating layer on an opposite side with respect to the second conductor layer, and the build-up layer is formed such that the first insulating layer and the second insulating layer contain no core material and that each of the third insulating layer and the fourth insulating layer includes a core material.

2. The wiring substrate according to claim 1, wherein the build-up layer includes at least one insulating layer laminated between the third insulating layer and the fourth insulating layer such that the at least one insulating layer contains no core material.

3. The wiring substrate according to claim 1, wherein the core material is a glass fiber.

4. The wiring substrate according to claim 1, further comprising:
a solder resist layer formed on the first insulating layer and the first conductor layer.

5. The wiring substrate according to claim 1, wherein the build-up layer includes a conductor pad embedded in the second insulating layer forming the second surface of the build-up layer such that the conductor pad has a surface exposed on the second surface of the build-up layer.

6. The wiring substrate according to claim 1, further comprising:
a plurality of via conductors formed in the insulating layers such that each of the via conductors has a diameter reducing from the first surface of the build-up layer toward the second surface of the build-up layer.

7. The wiring substrate according to claim 1, wherein the build-up layer is formed such that each of the conductor layers has a two-layer structure comprising an electroless plating film layer and an electrolytic plating film layer.

8. The wiring substrate according to claim 2, wherein the core material is a glass fiber.

9. The wiring substrate according to claim 2, further comprising:
a solder resist layer formed on the first insulating layer and the first conductor layer.

10. The wiring substrate according to claim 2, wherein the build-up layer includes a conductor pad embedded in the second insulating layer forming the second surface of the build-up layer such that the conductor pad has a surface exposed on the second surface of the build-up layer.

11. The wiring substrate according to claim 2, further comprising:
a plurality of via conductors formed in the insulating layers such that each of the via conductors has a diameter reducing from the first surface of the build-up layer toward the second surface of the build-up layer.

12. The wiring substrate according to claim 2, wherein the build-up layer is formed such that each of the conductor layers has a two-layer structure comprising an electroless plating film layer and an electrolytic plating film layer.

13. The wiring substrate according to claim 3, further comprising:
a solder resist layer formed on the first insulating layer and the first conductor layer.

14. The wiring substrate according to claim 3, wherein the build-up layer includes a conductor pad embedded in the second insulating layer forming the second surface of the build-up layer such that the conductor pad has a surface exposed on the second surface of the build-up layer.

15. The wiring substrate according to claim 3, further comprising:
a plurality of via conductors formed in the insulating layers such that each of the via conductors has a diameter reducing from the first surface of the build-up layer toward the second surface of the build-up layer.

16. The wiring substrate according to claim 3, wherein the build-up layer is formed such that each of the conductor layers has a two-layer structure comprising an electroless plating film layer and an electrolytic plating film layer.

17. The wiring substrate according to claim 4, wherein the build-up layer includes a conductor pad embedded in the second insulating layer forming the second surface of the build-up layer such that the conductor pad has a surface exposed on the second surface of the build-up layer.

18. The wiring substrate according to claim 4, further comprising:
a plurality of via conductors formed in the insulating layers such that each of the via conductors has a diameter reducing from the first surface of the build-up layer toward the second surface of the build-up layer.

19. The wiring substrate according to claim 4, wherein the build-up layer is formed such that each of the conductor layers has a two-layer structure comprising an electroless plating film layer and an electrolytic plating film layer.

20. The wiring substrate according to claim 5, further comprising:
a plurality of via conductors formed in the insulating layers such that each of the via conductors has a diameter reducing from the first surface of the build-up layer toward the second surface of the build-up layer.
